(19) United States
(12) Patent Application Publication
(10) Pub. No.: US 2025/0374650 A1
(43) Pub. Date: Dec. 4, 2025

(54) INTEGRATED PROCESS FOR FORMING SIGE CHANNEL IN NANOSHEET ARCHITECTURES

(71) Applicant: Applied Materials, Inc., Santa Clara, CA (US)

(72) Inventors: Joseph Francis Shepard, JR., Saratoga Springs, NY (US); Lydia Jane Kuebler, Schenectady, NY (US); Raman Gaire, Mechanicville, NY (US); Yan Yan, Rexford, NY (US)

(73) Assignee: Applied Materials, Inc., Santa Clara, CA (US)

(21) Appl. No.: 19/226,439

(22) Filed: Jun. 3, 2025

Related U.S. Application Data
(60) Provisional application No. 63/656,077, filed on Jun. 4, 2024.

(51) Int. Cl. H10D 84/01; H01L 21/225; H01L 21/324; H10D 30/00; H10D 30/01; H10D 30/43; H10D 62/10; H10D 62/60; H10D 62/832; H10D 84/85

(52) U.S. Cl. CPC H10D 84/0167; H01L 21/2254; H01L 21/324; H10D 30/014; H10D 30/0191; H10D 62/102; H10D 62/60; H10D 62/832; H10D 30/43; H10D 30/503; H10D 62/121; H10D 84/851

(57) ABSTRACT

Semiconductor devices having nanosheet architectures, e.g., transistors such as horizontal gate-all-around (hGAA) structures, methods, and apparatuses for forming such semiconductor devices are described. The methods comprise forming a cladding material around each of a first plurality of nanosheets; oxidizing a portion of the cladding material to form an oxidize film, such as a silicon oxide (SiO₂) film, around the cladding material and a form a second plurality of nanosheets; annealing the second plurality of nanosheets at a temperature of less than or equal to 850° C.; and removing the oxide film.

### CROSS-REFERENCE TO RELATED APPLICATIONS

This application claims priority to U.S. Provisional Application No. 63/656,077, filed Jun. 4, 2024, the entire disclosure of which is hereby incorporated by reference herein.

### TECHNICAL FIELD

Embodiments of the present disclosure generally relate to semiconductor devices and more particularly to horizontal gate-all-around (hGAA) structures, methods, and apparatuses for forming horizontal gate-all-around (hGAA) structures.

### BACKGROUND

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (FinFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. FinFETs, however, have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor structures include a planar structure, a fin field effect transistor (FinFET) structure, and a horizontal gate-all-around (hGAA) structure. The horizontal gate-all-around (hGAA) structure includes several lattice matched channels suspended in a stacked configuration and connected by source/drain regions. It has been found that the horizontal gate-all-around (hGAA) structure provides good electrostatic control and can find broad adoption in complementary-metal-oxide-semiconductor (CMOS) wafer manufacturing.

Generally, a metal oxide semiconductor (MOS) is a structure obtained by growing a layer of silicon dioxide (SiO₂) on top of a silicon substrate and then depositing a layer of metal or polycrystalline silicon. A CMOS device is a MOS device consisting of paired p-channel and n-channel transistors. An “NMOS” or “NFET” is a MOS transistor where the active carriers are electrons flowing between n-type source and drain regions in an electrostatically formed n-channel in a p-type silicon substrate. The abbreviations “NMOS” and “NFET” can be used interchangeably herein. A “PMOS” or “PFET” is a P-channel MOS transistor where the active carriers are holes flowing between p-type source and drain regions in an electrostatically formed p-channel in an n-type silicon substrate. The abbreviations “PMOS” and “PFET” can be used interchangeably herein.

Accordingly, a “PMOS” or “PFET” comprises a silicon germanium (SiGe) channel between a source and drain region and the “NMOS” or “NFET” comprises a silicon (Si) channel between a source region and a drain region.

A silicon germanium (SiGe) channel is one attractive feature for a gate-all-around (GAA) (nanowire or nanosheet) to achieve a high mobility “PMOS” or “PFET”. One method is to form a uniform silicon germanium (SiGe) layer around the silicon nanosheet, which can be referred to as an “epitaxial cladding process”, then continue with gate stack processing. Traditional gate stack processing operations are performed at high temperatures, such as 1000° C., which is too hot for gate-all-around (GAA) architectures. For example, dopants at the junction, such as the source/drain junctions, will diffuse and degrade device performance.

Accordingly, there is a need for improved methods of manufacturing semiconductor devices, e.g., horizontal gate-all-around (hGAA) structures, at lower temperatures.

### SUMMARY

One or more embodiments of the disclosure are directed to methods of manufacturing a semiconductor device. In one or more embodiments, the method comprises: forming a cladding material around each of a plurality of nanosheets; oxidizing a portion of the cladding material to form an oxide film around the cladding material; annealing the plurality of nanosheets at a temperature of less than or equal to 850° C.; and removing the oxide film from the cladding material.

Further embodiments are directed to methods of manufacturing a semiconductor device. In one or more embodiments, the method comprises: selectively etching a superlattice structure on a substrate, the superlattice structure comprising a plurality of first layers of silicon (Si) and a plurality of second layers of silicon germanium (SiGe) alternatingly arranged in a plurality of stacked pairs extending between a source region and a drain region, the source region formed adjacent a first end of the superlattice structure and the drain region formed adjacent a second opposing end of the superlattice structure. In one or more embodiments, selectively etching the superlattice structure removes each of the plurality of second layers to form a plurality of voids in the superlattice structure and a first plurality of nanosheets comprising the plurality of first layers. In one or more embodiments, the method further comprises forming a cladding material around each of the first plurality of nanosheets; oxidizing a portion of the cladding material to form an oxide film around the cladding material and form a second plurality of nanosheets; annealing the second plurality of nanosheets at a temperature of less than or equal to 850° C.; and removing the oxide film.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a process flow diagram of a method of manufacturing a semiconductor device in accordance with one or more embodiments of the present disclosure;

FIG. 2 illustrates a cross-sectional view of a substrate in accordance with one or more embodiments of the present disclosure;

FIG. 3 illustrates a cross-sectional view of a substrate in accordance with one or more embodiments of the present disclosure;

FIG. 4 illustrates a cross-sectional view of a substrate in accordance with one or more embodiments of the present disclosure;

FIG. 5 illustrates a cross-sectional view of a substrate in accordance with one or more embodiments of the present disclosure;

FIG. 6 illustrates a cross-sectional view of a substrate in accordance with one or more embodiments of the present disclosure;

FIG. 7 illustrates a cross-sectional view of a substrate in accordance with one or more embodiments of the present disclosure;

FIG. 8 illustrates a cross-sectional view of a substrate in accordance with one or more embodiments of the present disclosure;

FIG. 9 illustrates a cross-sectional view of a substrate in accordance with one or more embodiments of the present disclosure;

FIG. 10 illustrates a cross-sectional view of a substrate in accordance with one or more embodiments of the present disclosure; and

FIG. 11 illustrates a schematic representation of a multi-chamber processing system in accordance with one or more embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the Figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “some embodiments,” “certain embodiments,” “one or more embodiments,” or “an embodiment” means that a particular feature, structure, material, or characteristic described in connection with the embodiment is included in at least one embodiment of the disclosure. Thus, the appearances of the phrases such as “in one embodiment,” “in some embodiments,” “in certain embodiments,” “in one or more embodiments,” or “in an embodiment” in various places throughout this specification are not necessarily referring to the same embodiment of the disclosure. Furthermore, the particular features, structures, materials, or characteristics may be combined in any suitable manner in one or more embodiments.

As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, and any other materials such as metals, metal nitrides, metal alloys, and other conductive materials, depending on the application. Substrates include, without limitation, semiconductor substrates. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The substrate may have one or more features formed therein, one or more layers formed thereon, or combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls comprising, for example, a dielectric material, and a bottom extending into the substrate, the bottom comprising, for example, a metallic material, or vias which have one or more sidewall extending into the substrate to a bottom, and slot vias.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, 40:1, 50:1, 60:1, 70:1, 80:1, 90:1, 100:1, 125:1, or 150:1. In one or more embodiments, the aspect ratio of the features described herein is in a range of from 1:1 to 150:1.

The term “on” indicates that there is contact between elements, and there may be intervening elements or layers. The term “directly on” indicates that there is direct contact between elements with no intervening elements.

As used in this specification and the appended claims, the terms “precursor,” “reactant,” “reactive gas” and the like are used interchangeably to refer to any gaseous species that can react with the substrate surface.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

As used herein, as will be understood by the skilled artisan, a layer/film which is “conformal” or “conformally deposited” refers to a layer/film where the thickness is about the same throughout. A layer/film which is conformal varies in thickness by less than or equal to about 5%, 2%, 1% or 0.5%.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate. In one or ore more embodiments, the gate surrounds all of the nanosheets between the bottom substrate and above channels.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated Is and current entering the channel at the drain (D) is designated ID. Drain-to-source voltage is designated VDs. By applying voltage to gate (G), the current entering the channel at the drain (i.e., ID) can be controlled.

The metal-oxide-semiconductor field-effect transistor (MOSFET) is a type of field-effect transistor (FET). The MOSFET has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

Generally, a metal oxide semiconductor (MOS) is a structure obtained by growing a layer of silicon dioxide (SiO₂) on top of a silicon substrate and then depositing a layer of metal or polycrystalline silicon. A CMOS device is a MOS device consisting of paired p-channel and n-channel transistors.

If the MOSFET is an n-channel or NMOS FET (′NMOS″ or “NFET”), then the source and drain are n+ regions and the body is a p region. If the MOSFET is a p-channel or PMOS FET (“PMOS” or “PFET”), then the source and drain are p+ regions and the body is an n region. The source is so named because it is the source of the charge carriers (electrons for n-channel, holes for p-channel) that flow through the channel; similarly, the drain is where the charge carriers leave the channel.

An “NMOS” or “NFET” is a MOS transistor where the active carriers are electrons flowing between n-type source and drain regions in an electrostatically formed n-channel in a p-type silicon substrate. A “PMOS” or “PFET” is a P-channel MOS transistor where the active carriers are holes flowing between p-type source and drain regions in an electrostatically formed p-channel in an n-type silicon substrate.

Accordingly, a “PMOS” or “PFET” comprises a silicon germanium (SiGe) channel between a source and drain region and the “NMOS” or “NFET” comprises a silicon (Si) channel between a source region and a drain region.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “gate-all-around (GAA),” is used to refer to an electronic device, e.g., a transistor, in which the gate material surrounds the channel region on all sides. The channel region of a GAA transistor may include nanowires, nanosheets, nanoslabs, bar-shaped channels, or other suitable channel configurations known to one of skill in the art. In one or more embodiments, the channel region of a GAA transistor has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10-9 meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm.

A silicon germanium (SiGe) channel is one attractive feature for a gate-all-around (GAA) structure (nanowire or nanosheet) to achieve a high mobility “PMOS” or “PFET”. One method is to form a uniform silicon germanium (SiGe) layer around the silicon nanosheet, which can be referred to as an “epitaxial cladding process”, then continue with gate stack processing. It has been found that forming uniform silicon germanium (SiGe) layer around the silicon nanosheet via an epitaxial cladding process requires conformal deposition of a dielectric film (such as an oxide film or a nitride film) around the uniform silicon germanium (SiGe) layer around the silicon nanosheet. After conformal deposition of the dielectric film, which can be referred to as a “cap,” the stack is annealed at temperatures greater than 850° C. for extended periods of time (greater than 10 min). After annealing, the conformally deposited cap is removed completely with high selectivity to the uniform silicon germanium (SiGe) layer.

After removal of the conformally deposited cap, in conventional condensation approaches, the silicon germanium (SiGe) layer is oxidized at a high temperature, typically 1000° C. or higher, which is sufficient to consume the silicon germanium (SiGe) layer around the silicon nanosheet and diffuse the germanium (Ge) to form silicon germanium (SiGe) nanosheets. Traditional condensation at 1000° C., however, is too hot for gate-all-around (GAA) architectures. For example, dopants at the junction, such as the source/drain junctions, will diffuse and degrade device performance.

Embodiments of the disclosure are directed to integrated processes for forming a silicon germanium (SiGe) channel in nanosheet architectures, e.g., a gate-all-around (GAA) structure.

One or more embodiments advantageously provide methods of forming a silicon germanium (SiGe) channel in a gate-all-around (GAA) structure with a low thermal budget. In one or more embodiments, the silicon germanium (SiGe) channel is formed using an integrated condensation-anneal-etch approach. Unlike with conventional high temperature anneals that degrade junction designs, the methods of one or more embodiments advantageously result in minimal to no degradation of the gate-all-around (GAA) structure.

One or embodiments advantageously provide an incremental process to diffuse germanium (Ge) from a silicon germanium (SiGe) layer surrounding a single crystal silicon (Si) channel into said single crystal silicon (Si) channel to form a silicon germanium (SiGe) channel at reduced temperatures without deposition of a dielectric film around the silicon germanium (SiGe) layer.

One or more embodiments of the disclosure are directed to methods of forming horizontal gate-all-around (hGAA) structures. Some embodiments advantageously provide integrated methods for forming complementary-metal-oxide-semiconductor (CMOS) devices with a uniform silicon germanium (SiGe) channel for PMOS while maintaining a silicon (Si) channel material for NMOS. In one or more embodiments where the uniform silicon germanium (SiGe) channel is formed using the integrated condensation-anneal-etch approach described herein, there is advantageously minimal to no degradation of the gate-all-around (GAA) structure.

The embodiments of the disclosure are described by way of the Figures, which illustrate semiconductors devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

One or more embodiments of the disclosure are described with reference to the Figures. In the method of one or more embodiments, transistors, e.g., gate-all-around (GAA) transistors, are fabricated using a standard process flow. In some embodiments, a method for forming the hGAA structures is augmented to use the integrated condensation-anneal-etch approach as described herein.

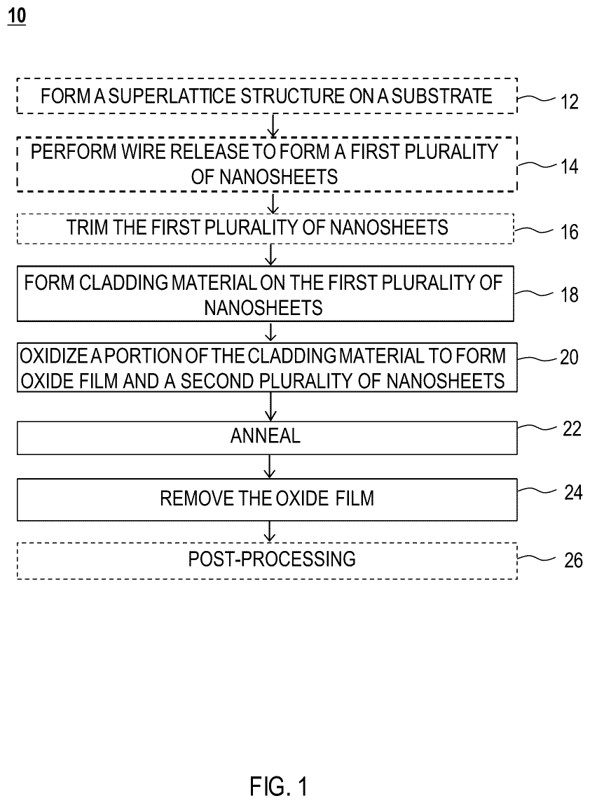

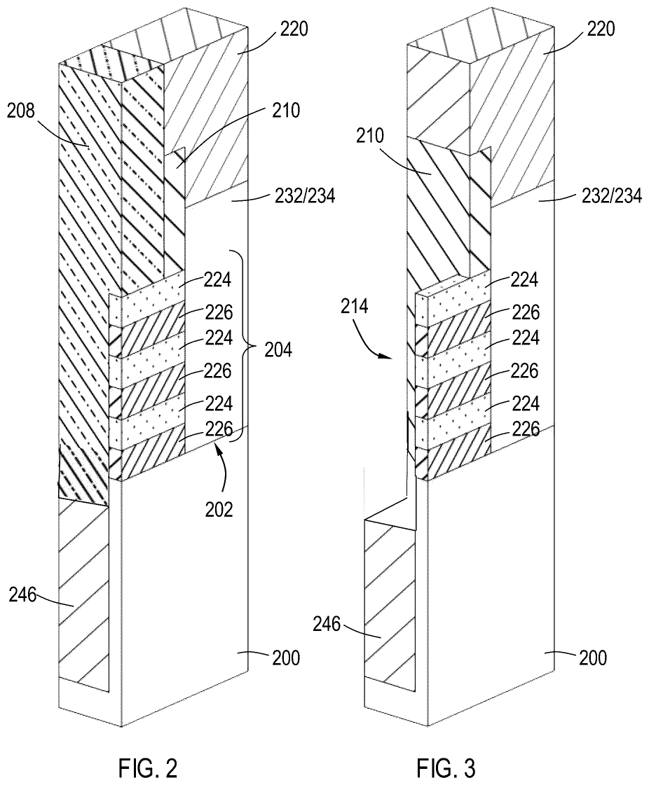

FIG. 1 illustrates a process flow diagram for a method 10 for forming a semiconductor device in accordance with some embodiments of the present disclosure. The method 10 is described below with respect to FIGS. 2-10, which depict the stages of fabrication of semiconductor structures, specifically gate-all-around (GAA) structures) in accordance with one or more embodiments of the present disclosure. In one or more embodiments, the method 10 is a method of forming a transistor, e.g., a transistor having a nanosheet architecture such as a gate-all-around (GAA) structure. The method 10 of one or more embodiments may be part of a multi-step fabrication process of a semiconductor device and/or an electronic device.

The method may be performed in any suitable process chamber coupled to a cluster tool (i.e., a multi-chamber processing system). The multi-chamber processing system may include process chambers for fabricating a semiconductor device, such as chambers configured for etching, deposition, atomic layer deposition (ALD), physical vapor deposition (PVD), chemical vapor deposition (CVD), annealing, oxidation, or any other suitable chamber used for the fabrication of a semiconductor device and/or an electronic device.

In one or more embodiments, the method 10 comprises operation 12, operation 14, operation 16, operation 18, operation 20, operation 22, operation 24, and operation 26. In one or more embodiments, the method 10 consists essentially of operation 12, operation 14, operation 16, operation 18, operation 20, operation 22, operation 24, and operation 26. In one or more embodiments, the method 10 consists of operation 12, operation 14, operation 16, operation 18, operation 20, operation 22, operation 24, and operation 26. In one or more embodiments, the method 10 consists of operation 18, operation 20, operation 22, operation 24, and operation 26.

The method 10 begins at operation 12, by optionally forming a superlattice structure 204 on a top surface 202 of a substrate 200 (as illustrated in FIG. 2). The substrate 200 can be provided (e.g., made available for processing) by being placed within a suitable processing chamber.

In some embodiments, the substrate 200 may be a bulk semiconductor substrate. The term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconductor substrate may comprise one or more materials such as crystalline silicon (e.g., Si<100> or Si<111>), silicon oxide, strained silicon, silicon germanium (SiGe), doped or undoped polysilicon, doped or undoped silicon wafers, patterned or non-patterned wafers, doped silicon, germanium (Ge), or other suitable semiconducting materials. In some embodiments, the semiconductor material is silicon (Si). In some embodiments, the semiconductor material may be a doped material, such as n-doped silicon (n-Si), or p-doped silicon (p-Si). In some embodiments, the substrate 200 may be doped using any suitable process such as an ion implantation process. In some embodiments, the substrate 200 may be doped to provide a high dose of dopant at the top surface 202 of the substrate 200 in order to prevent parasitic bottom device turn on. For example, in some embodiments, the top surface 202 the substrate 200 may have a dopant density about 10¹⁸ atoms/cm³ to about 10¹⁹ atoms/cm³.

In one or more embodiments, the superlattice structure 204 is formed directly on the top surface 202 of the substrate 200. In one or more embodiments, the substrate 200 is provided (e.g., made available for processing) with the superlattice structure 204 already formed directly on the top surface 202 of the substrate 200. Accordingly, operation 12 of method 10 is denoted as optional by using dashed lines.

The superlattice structure 204 comprises a plurality of first layers 224 and a plurality of second layers 226 alternatingly arranged in a plurality of stacked pairs. In some embodiments, the plurality of stacked pairs comprises a silicon (Si) group and silicon germanium (SiGe) group. In some embodiments, the plurality of first layers 224 comprise silicon (Si). In some embodiments, the plurality of second layers 226 comprise silicon germanium (SiGe). In some embodiments, the plurality of first layers 224 and the plurality of second layers 226 can each independently comprise any number of lattice matched material pairs suitable for forming a superlattice structure 204. In some embodiments, the plurality of first layers 224 and corresponding plurality of second layers 226 comprise from 2 to 50 pairs, or from 2 to 20 pairs of lattice matched materials.

Typically, a parasitic device will exist at the bottom of the superlattice structure 204 (e.g., on the top surface 202 of the substrate 200). In some embodiments, implant of a dopant in the substrate 200, as discussed above, is used to suppress the turn on of the parasitic device. In some embodiments, the substrate 200 is etched so that the bottom portion of the superlattice structure 204 includes a substrate portion which is not removed, allowing the substrate portion to act as the bottom release layer of the superlattice structure 204.

The thicknesses of the plurality of first layers 224 and the plurality of second layers 226 in some embodiments are in the range of about 2 nm to about 50 nm, or in the range of about 3 nm to about 20 nm. In some embodiments, the average thickness of the plurality of first layers 224 is within 0.5 to 2 times the average thickness of the plurality of second layers 226.

In some embodiments, a dielectric material 246 is deposited on the substrate 200 using conventional chemical vapor deposition (CVD) methods. In some embodiments, the dielectric material 246 is recessed below the top surface 202 of the substrate 200 so that the bottom portion of the superlattice structure 204 is formed from the substrate 200.

In some embodiments, a replacement gate structure (e.g., a dummy gate structure 208) is formed over the superlattice structure 204. The dummy gate structure 208 defines the channel region of the transistor device. The dummy gate structure 208 may be formed using any suitable conventional deposition and patterning process known in the art.

In some embodiments, sidewall spacers 210 are formed along outer sidewalls of the dummy gate structure 208. The sidewall spacers 210 of some embodiments comprise suitable insulating materials known in the art, for example, silicon nitride (SiN), silicon oxide (SiOx), silicon oxynitride (SiON), silicon carbide (SiC), or the like. In some embodiments, the sidewall spacers 210 are formed using any suitable conventional deposition and patterning process known in the art, such as atomic layer deposition (ALD), plasma-enhanced atomic layer deposition (PEALD), plasma-enhanced chemical vapor deposition (PECVD), or low-pressure chemical vapor deposition (CVD).

In some embodiments, an embedded source region 232 and drain region 234 form in a source trench and a drain trench, respectively. In some embodiments, the source region 232 is formed adjacent a first end of the superlattice structure 204 and the drain region 234 is formed adjacent a second, opposing end of the superlattice structure 204. In the embodiment illustrated in FIG. 2, the one of the source region 232 or the drain region 234 is not shown at the front face of the superlattice structure 204. The other end of the superlattice structure 204 has the other of the source region 232 or the drain region 234. In some embodiments, the source region 232 and/or drain region 234 are formed from any suitable semiconductor material, including but not limited to silicon (Si), germanium (Ge), silicon germanium (SiGe), or the like. In some embodiments, the source region 232 and drain region 234 may be formed using any suitable deposition process, such as an epitaxial deposition process.

In some embodiments, an interlayer dielectric (ILD) layer 220 is blanket deposited over the substrate 200, including the source region 232, the drain region 234, the dummy gate structure 208, and the sidewall spacers 210. The ILD layer 220 may be deposited using a conventional chemical vapor deposition (CVD) method (e.g., plasma-enhanced chemical vapor deposition (PECVD) and low-pressure chemical vapor deposition (CVD)). In an embodiment, ILD layer 220 is formed from any well-known dielectric material such as, but not limited to undoped silicon oxide, doped silicon oxide (e.g., BPSG, PSG), silicon nitride (SiN), and silicon oxynitride (SiON). The ILD layer 220 is then polished back using a conventional chemical mechanical planarization (CMP) method to expose the top of the dummy gate structure 208. In one or more unillustrated embodiments, the ILD layer 220 is polished to expose the top of the dummy gate structure 208 and the top of the sidewall spacers 210.

In some embodiments, as illustrated in FIG. 3, the dummy gate structure 208 is removed to expose the channel region 214 of the superlattice structure 204. The ILD layer 220 protects the source region 232 and the drain region 234 during the removal of the dummy gate structure 208. The dummy gate structure 208 may be removed using a conventional etching method such plasma dry etch or a wet etch. In some embodiments, the dummy gate structure 208 comprises poly-silicon and the dummy gate structure 208 is removed by a selective etch process. In some embodiments, the dummy gate structure 208 comprises poly-silicon and the superlattice structure 204 comprises alternating layers of silicon (Si) and silicon germanium (SiGe). In some embodiments, the dummy gate structure 208 comprises poly-silicon and the superlattice structure 204 comprises alternating layers of silicon (Si) (e.g., the plurality of first layers 224) and silicon germanium (SiGe) (e.g., the plurality of second layers 226).

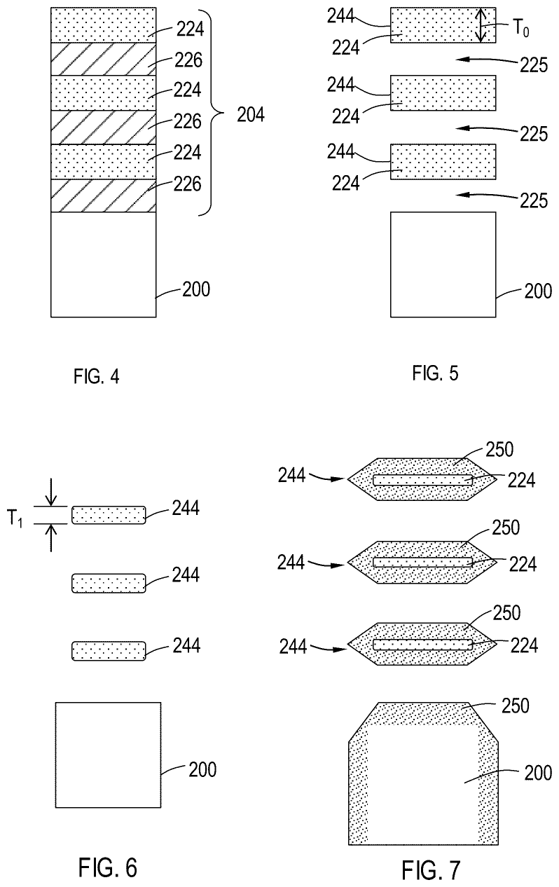

FIG. 4 illustrates the relevant portion of the substrate 200 of FIG. 3 showing an end-on view of the superlattice structure 204 with the plurality of first layers 224 and the plurality of second layers 226. In operation 14 of method 10, as illustrated in FIG. 5, a wire release process selectively etches between the plurality of first layers 224 in the superlattice structure 204 to remove the plurality of second layers 226. The wire release process forms a plurality of voids 225 between each of the plurality of first layers 224 resulting in a first plurality of nanosheets 244 comprising the plurality of first layers 224 extending between the source region 232 and drain region 234.

For example, where the superlattice structure 204 is composed of the plurality of first layers 224 comprising silicon (Si) and the plurality of second layers 226 comprising silicon germanium (SiGe), the plurality of second layers 226 comprising silicon germanium (SiGe) is selectively etched to form channel nanowires (also referred to as nanosheets). The plurality of second layers 226 comprising silicon germanium (SiGe) may be removed using any well-known etchant that is selective to the plurality of first layers 224 comprising silicon (Si) where the etchant etches the plurality of second layers 226 at a significantly higher rate than the plurality of first layers 224 comprising silicon (Si). In some embodiments, a selective dry etch or wet etch process may be used. In some embodiments, a wet etchant such as, but not limited to aqueous carboxylic acid/nitric acid/HF solution and aqueous citric acid/nitric acid/HF solution is used. The removal of the plurality of second layers 226 leaves voids 225 between the each of the plurality of first layers 224. The voids 225 between each of the plurality of first layers 224 have a thickness of about 3 nm to about 20 nm. The remaining each of plurality of first layers 224 form a vertical array of channel nanowires that are coupled to the source region 232 and the drain region 234. The channel nanowires run parallel to the top surface 202 of the substrate 200 and are aligned with each other to form a single column of channel nanowires. The formation of the source region 232 and the drain region 234 and the formation of an optional lateral etch stop layer (not shown) advantageously provide self-alignment and structural integrity in the formation of the channel structure.

In one or more embodiments, the substrate 200 is provided (e.g., made available for processing) with the superlattice structure 204 already formed directly on the top surface 202 of the substrate 200 in accordance with optional operation 12, and the wire release process of operation 14 already performed to form the plurality of nanosheets 244. Accordingly, operation 14 of method 10 is denoted as optional by using dashed lines.

At optional operation 16, as illustrated in FIG. 6, the first plurality of nanosheets 244 is exposed to a process in which each of the first plurality of nanosheets 244 are trimmed from an initial thickness T₀ (as shown in FIG. 5) to a nanosheets 244 having a reduced thickness T₁ (as shown in FIG. 6).

The first plurality of nanosheets 244 can be trimmed by any suitable etch process known to the skilled artisan that is compatible with the plurality of first layers 224. In some embodiments, the first plurality of nanosheets 244 is trimmed by exposure to a wet etch process, such as aqueous alkaline media like KOH—, NaOH— or TMAH-solutions. In some embodiments, the first plurality of nanosheets 244 is trimmed by exposure to a dry etch process. In one or more embodiments, the dry etch process includes exposing the first plurality of nanosheets 244 to common gases for etching the silicon, reactive ion etching (RIE) with a remote plasma source, ammonia (NH₃), and hydrogen (H₂).

The reduction in thickness of the first plurality of nanosheets 244 according to some embodiments is greater than or equal to 50% of the initial thickness T₀. In some embodiments, the initial thickness T₀ is in a range of from 4 nm to 10 nm, or in the range of from 5 nm to 9 nm, or in the range of from 6 nm to 8 nm. In some embodiments, the reduced thickness T₁ is in the range of ⅓ to ⅕ of initial thickness T₀, or in the range of from 1 nm to 3 nm. In some embodiments, trimming the first plurality of nanosheets 244 reduces the thickness of the first plurality of nanosheets 244 from an initial thickness T₀ in the range of from 6 nm to 8 nm to a reduced thickness T₁ in the range of from 1 nm to 3 nm, or in a range of from 2 nm to 3 nm.

In one or more embodiments, the substrate 200 is provided (e.g., made available for processing) with the superlattice structure 204 already formed directly on the top surface 202 of the substrate 200 in accordance with optional operation 12, the wire release process of optional operation 14 already performed to form the first plurality of nanosheets 244, and the first plurality of nanosheets 244 already trimmed in accordance with operation 16. Accordingly, operation 16 of method 10 is denoted as optional by using dashed lines.

At operation 18, a cladding material 250 is formed around each of the first plurality of nanosheets 244, which include the plurality of first layers 224. The cladding material 250 is formed on the first plurality of nanosheets 244 whether or not optional operation 12, optional operation 14, and/or optional operation 16 is performed. As described herein, the method 10 can begin with operation 18 where the substrate 200 is provided (e.g., made available for processing) with the superlattice structure 204 already formed directly on the top surface 202 of the substrate 200 in accordance with optional operation 12, the wire release process of optional operation 14 already performed to form the first plurality of nanosheets 244, and the first plurality of nanosheets 244 already trimmed in accordance with operation 16.

The cladding material 250 can be formed by any suitable process known to the skilled artisan. In some embodiments, the cladding material 250 comprises silicon germanium (SiGe) or germanium (Ge). In some embodiments, the cladding material 250 comprises, consists essentially of, or consists of silicon germanium (SiGe). In one or more embodiments, the cladding material 250 comprises an initial concentration in a range of from 15% to 50% germanium (Ge).

In some embodiments, the cladding material 250 is epitaxially grown on the first plurality of nanosheets 244. In one or more embodiments, the cladding material 250 may be fabricated via chemical vapor deposition (CVD) epitaxy with a temperature in a range of from 450° C. to 850° C.

In one or more embodiments, the cladding material 250 has any suitable thickness. In some embodiments, the cladding material 250 has a thickness in a range of from 2 nm to 5 nm.

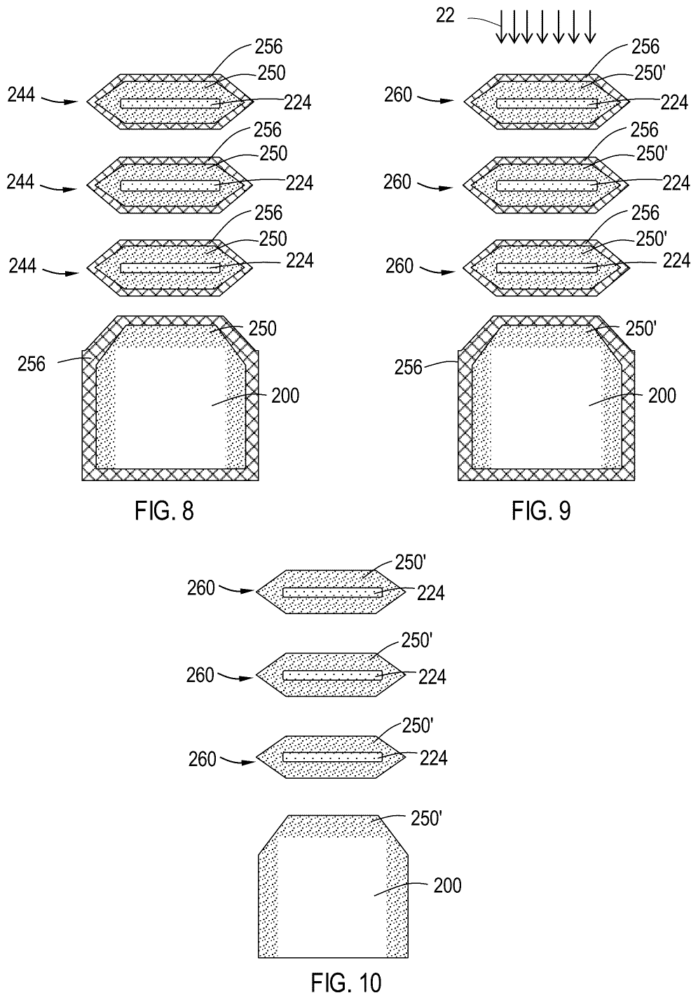

Referring to FIG. 1 and FIG. 8, at operation 20, the method 10 comprises oxidizing a portion of the cladding material 250 to form an oxide film 256 around the cladding material 250. The reference numeral 250′ is used to denote a treated cladding material, formed in accordance with operation 20 of the method 10. The treated cladding material 250′ has an increased concentration in a range of from greater than 50% to 65% germanium (Ge).

The oxide film 256 can include any oxide material. In one or more embodiments, the oxide film 256 comprises, consists essentially of, or consists of silicon oxide (SiO₂).

In one or more embodiments, the oxide film 256 has a thickness in a range of from 1 nm to 50 nm. In one or more embodiments, oxidizing at operation 20 comprises one or more of a rapid thermal oxidation (RTO) process, a rapid thermal anneal (RTA) process, and a rapid plasma oxidation (RPO) process.

In one or more embodiments, oxidizing at operation 20 comprises one or more of a rapid thermal oxidation (RTO) process, a rapid thermal anneal (RTA) process, and a rapid plasma oxidation (RPO) process, causes germanium (Ge) from the treated cladding material 250′ to diffuse into the first plurality of nanosheets 244. In some embodiments, the RPO process comprises an exposure to an oxygen-containing plasma (e.g., molecular oxygen (O₂), ozone (O₃)) at a temperature in the range of 350° C. to 9000° C., or at a temperature in the range of from 350° C. to 800° C. to form the treated cladding material 250′. In some embodiments, the RPO process comprises an exposure to an oxygen-containing plasma (e.g., one or more of molecular oxygen (O₂) or ozone (O₃)) at a pressure ranging from 5 torr to 600 torr to form the treated cladding material 250′.

During the rapid thermal oxidation (RTO) process/rapid thermal anneal (RTA) process, the process environment of some embodiments comprises one or more of oxygen (O₂), ozone (O₃), hydrogen (H₂), in some cases under mixture of O₂/N₂, or H₂/O₂, or H₂/N₂ gases.

The rapid thermal oxidation (RTO) process/rapid thermal anneal (RTA) process results in rearrangement of the germanium (Ge) atoms in the first plurality of nanosheets 244 so that the cladding material 250 effectively replaces the material of the plurality of first layers 224 (e.g., silicon (Si)). In one or more embodiments, removing the material of the plurality of first layers 224 (e.g., silicon (Si)) from the first plurality of nanosheets 244 comprises oxidizing a portion of the cladding material 250, and oxidizing comprises one or more of the rapid thermal oxidation (RTO) process, the rapid thermal anneal (RTA) process, or the rapid plasma oxidation (RPO) process to cause germanium (Ge) from the cladding material 250 to diffuse into the plurality of first layers 224, effectively removing/replacing the silicon (Si) of the plurality of first layers 224 with silicon germanium (SiGe).

FIG. 9 illustrates a second plurality of nanosheets 260 formed by oxidizing at operation 20. The second plurality of nanosheets 260 comprises, consists essentially of, or consists of silicon germanium (SiGe). In one or more embodiments, the second plurality of nanosheets 260 defines a uniform silicon germanium (SiGe) channel for a nanosheet architecture. In one or more embodiments, the second plurality of nanosheets 260 defines a uniform silicon germanium (SiGe) channel comprising, consisting essentially of, or consisting of the treated cladding material 250′ having an increased concentration in a range of from greater than 50% to 65% germanium (Ge). In one or more embodiments, the second plurality of nanosheets 260 defines a uniform silicon germanium (SiGe) channel for PMOS, while a silicon (Si) channel material is used for NMOS.

Referring to FIG. 1 and FIG. 9, at operation 22 of method 10, the second plurality of nanosheets 260 is annealed by any suitable annealing process at a temperature of less than or equal to 850° C. In one or more embodiments, the second plurality of nanosheets 260 is annealed by any suitable annealing process at a temperature in a range of from 500° C. to 850° C.

Referring to FIG. 1 and FIG. 10, at operation 24 of method 10, the oxide film 256 is removed by any suitable etch process. In some embodiments, removing the oxide film 256 comprises exposing the substrate 200 to a solution of dilute hydrofluoric acid (˜1:100-1:150 HF:H₂O) at room temperature, or exposing the substrate 200 to a solution of hot phosphoric acid (H₂PO₄) at about 165° C.

FIG. 10 illustrates the second plurality of nanosheets 260, e.g., the uniform silicon germanium (SiGe) channel, after removing the oxide film 256 at operation 24.

The method 10 optionally includes one or more processes (“post-processing” at operation 26) after removing the oxide film 256 at operation 24. The post-processing operation 26 can be any of the processes known to the skilled artisan for completion of the transistor structures, e.g., the horizontal gate-all-around (hGAA) structure. For example, in one or more embodiments, a high-K metal gate is formed in accordance with optional operation 26. The high-K metal gate can be formed by any process known to the skilled artisan for completion of the transistor structures, e.g., the horizontal gate-all-around (hGAA) structure. In one or more embodiments, the high-K metal gate is formed in contact with the second plurality of nanosheets 260.

In one or more embodiments, a capping layer may be formed or grown on the plurality of first layers 224. The capping layer can be any suitable oxide formed by any suitable technique known to the skilled artisan. In some embodiments, the capping layer comprises a silicon capping layer.

In one or more unillustrated embodiments, a high-K dielectric layer may be formed on the capping layer. The high-K dielectric layer can be any suitable high-K dielectric material deposited by any suitable deposition technique known to the skilled artisan. The high-K dielectric layer of some embodiments comprises hafnium oxide. In some embodiments, a conductive material such as titanium nitride, tungsten, cobalt, aluminum, or the like may be formed on the high-K dielectric layer. The conductive material may be formed using any suitable deposition process such as atomic layer deposition (ALD) in order to ensure the formation of a layer having a uniform thickness around each of the plurality of first layers 224.

In some unillustrated embodiments, a gate electrode may be formed on the substrate 200 and surrounds each of the plurality of first layers 224. The gate electrode may be formed from any suitable gate electrode material known in the art. The gate electrode material is deposited using any suitable deposition process such as atomic layer deposition (ALD) to ensure that gate electrode is formed around and between each of the plurality of first layers 224. The resultant transistor formed using the method described herein is a horizontal gate-all-around (hGAA) structure, in accordance with an embodiment of the present disclosure. Some embodiments of the disclosure are directed to horizontal gate-all-around (hGAA) structures having a uniform silicon germanium (SiGe) channel formed in accordance with the method 10.

Some embodiments of the disclosure are directed to electronic devices comprising a PMOS and an NMOS. The PMOS comprises a silicon germanium (SiGe) channel between a source and drain region, formed in accordance with the methods described herein (e.g., the method 10) and the NMOS comprises a silicon (Si) channel between a source region and a drain region.

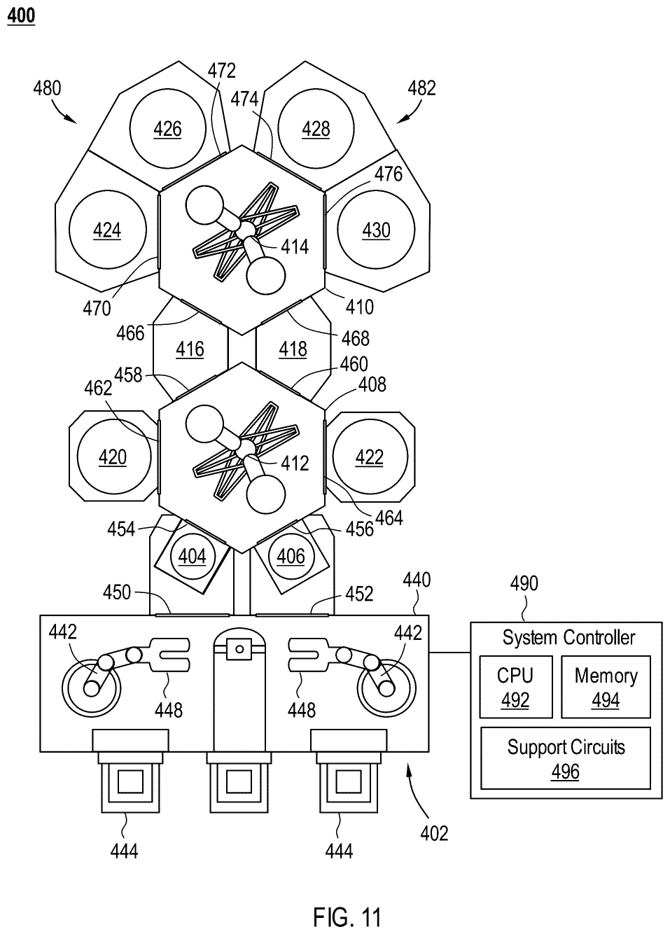

Some embodiments of the disclosure are directed to integrated processes which are performed within a single cluster tool, i.e., within a single multi-chamber processing system. FIG. 11 is a schematic top-view diagram of a multi-chamber processing system 400 according to one or more embodiments of the present disclosure. As used herein, the reference labels “multi-chamber processing system 400” and “processing system 400” can be used interchangeably with reference to FIG. 11. The processing system 400 generally includes a factory interface 402, load lock chambers 404, 406, transfer chambers 408, 410 with respective transfer robots 412, 414, holding chambers 416, 418, and processing chambers 420, 422, 424, 426, 428, 430. As detailed herein, wafers in the processing system 400 can be processed in and transferred between the various chambers without exposing the wafers to an ambient environment exterior to the processing system 400 (e.g., an atmospheric ambient environment such as may be present in a fab). For example, the wafers can be processed in and transferred between the various chambers in a low pressure (e.g., less than or equal to about 40 to 80 Torr) or vacuum environment without breaking the low pressure or vacuum environment between various processes performed on the wafers in the processing system 400. Accordingly, the processing system 400 may provide for an integrated solution for some processing of wafers.

In the illustrated example of FIG. 11, the factory interface 402 includes a docking station 440 and factory interface robots 442 to facilitate transfer of wafers. The docking station 440 is configured to accept one or more front opening unified pods (FOUPs) 444. In some examples, each factory interface robot 442 generally comprises a blade 448 disposed on one end of the respective factory interface robot 442 configured to transfer the wafers from the factory interface 402 to the load lock chambers 404, 406.

The load lock chambers 404, 406 have respective ports 450, 452 coupled to the factory interface 402 and respective ports 454, 456 coupled to the transfer chamber 408. The transfer chamber 408 further has respective ports 458, 460 coupled to the holding chambers 416, 418 and respective ports 462, 464 coupled to processing chambers 420, 422. Similarly, the transfer chamber 410 has respective ports 466, 468 coupled to the holding chambers 416, 418 and respective ports 470, 472, 474, 476 coupled to processing chambers 424, 426, 428, 430. The ports 454, 456, 458, 460, 462, 464, 466, 468, 470, 472, 474, 476 can be, for example, slit valve openings with slit valves for passing wafers therethrough by the transfer robots 412, 414 and for providing a seal between respective chambers to prevent a gas from passing between the respective chambers. Generally, any port is open for transferring a wafer therethrough. Otherwise, the port is closed.

The load lock chambers 404, 406, transfer chambers 408, 410, holding chambers 416, 418, and processing chambers 420, 422, 424, 426, 428, 430 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 442 transfers a wafer from a FOUP 444 through a port 450 or 452 to a load lock chamber 404 or 406. The gas and pressure control system then pumps down the load lock chamber 404 or 406. The gas and pressure control system further maintains the transfer chambers 408, 410 and holding chambers 416, 418 with an interior low pressure or vacuum environment (which may include an inert gas). Hence, the pumping down of the load lock chamber 404 or 406 facilitates passing the wafer between, for example, the atmospheric environment of the factory interface 402 and the low pressure or vacuum environment of the transfer chamber 408.

With the wafer in the load lock chamber 404 or 406 that has been pumped down, the transfer robot 412 transfers the wafer from the load lock chamber 404 or 406 into the transfer chamber 408 through the port 454 or 456. The transfer robot 412 is then capable of transferring the wafer to and/or between any of the processing chambers 420, 422 through the respective ports 462, 464 for processing and the holding chambers 416, 418 through the respective ports 458, 460 for holding to await further transfer. Similarly, the transfer robot 414 is capable of accessing the wafer in the holding chamber 416 or 418 through the port 466 or 468 and is capable of transferring the wafer to and/or between any of the processing chambers 424, 426, 428, 430 through the respective ports 470, 472, 474, 476 for processing and the holding chambers 416, 418 through the respective ports 466, 468 for holding to await further transfer. The transfer and holding of the wafer within and among the various chambers can be in the low pressure or vacuum environment provided by the gas and pressure control system.

The processing chambers 420, 422, 424, 426, 428, 430 can be any appropriate chamber for processing a wafer. In some embodiments, the processing chamber 420 can be capable of performing an annealing process, the processing chamber 422 can be capable of performing a cleaning process, and the processing chambers 424, 426, 428, 430 can be capable of performing epitaxial growth processes. In some examples, the processing chamber 422 can be capable of performing a cleaning process, the processing chamber 420 can be capable of performing an etch process, and the processing chambers 424, 426, 428, 430 can be capable of performing respective epitaxial growth processes.

A system controller 490 is coupled to the processing system 400 for controlling the processing system 400 or components thereof. For example, the system controller 490 may control the operation of the processing system 400 using a direct control of the chambers 404, 406, 408, 416, 418, 410, 420, 422, 424, 426, 428, 430 of the processing system 400 or by controlling controllers associated with the chambers 404, 406, 408, 416, 418, 410, 420, 422, 424, 426, 428, 430. In operation, the system controller 490 enables data collection and feedback from the respective chambers to coordinate performance of the processing system 400.

The system controller 490 generally includes a central processing unit (CPU) 492, memory 494, and support circuits 496. The CPU 492 may be one of any form of a general-purpose processor that can be used in an industrial setting. The memory 494, or non-transitory computer-readable medium, is accessible by the CPU 492 and may be one or more of memory such as random-access memory (RAM), read only memory (ROM), floppy disk, hard disk, or any other form of digital storage, local or remote. The support circuits 496 are coupled to the CPU 492 and may comprise cache, clock circuits, input/output subsystems, power supplies, and the like. The various methods disclosed herein may generally be implemented under the control of the CPU 492 by the CPU 492 executing computer instruction code stored in the memory 494 (or in memory of a particular process chamber) as, for example, a software routine. When the computer instruction code is executed by the CPU 492, the CPU 492 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 408, 410 and the holding chambers 416, 418. In other examples, more or fewer transfer chambers (e.g., one transfer chamber) and/or more or fewer holding chambers (e.g., no holding chambers) may be implemented as a transfer apparatus in a processing system.

One or more embodiments of the disclosure are directed to a non-transitory computer readable medium including instructions, that, when executed by a controller of a processing chamber (or processing system such as the processing system 400), cause the processing chamber (or processing system such as the processing system 400) to perform one or more of the operations of the method 10.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of manufacturing a semiconductor device, the method comprising:
forming a cladding material around each of a plurality of nanosheets;
oxidizing a portion of the cladding material to form an oxide film around the cladding material;
annealing the plurality of nanosheets at a temperature of less than or equal to 850° C.; and
removing the oxide film from the cladding material.

2. The method of claim 1, wherein each of the plurality of nanosheets comprises silicon (Si).

3. The method of claim 1, wherein the cladding material comprises silicon germanium (SiGe).

4. The method of claim 3, wherein the cladding material comprises an initial concentration in a range of from 15% to 50% germanium (Ge).

5. The method of claim 2, wherein oxidizing comprises one or more of a rapid thermal oxidation (RTO) process, a rapid thermal anneal (RTA) process, and a rapid plasma oxidation (RPO) process, to cause germanium (Ge) from the cladding material to diffuse into the plurality of nanosheets.

6. The method of claim 4, wherein oxidizing increases the initial concentration of the cladding material to an increased concentration in a range of from greater than 50% to 65% germanium (Ge).

7. The method of claim 1, comprising annealing the plurality of nanosheets at a temperature in a range of from 500° C. to 850° C.

8. The method of claim 1, wherein removing the oxide film comprises etching.

9. The method of claim 1, wherein the oxide film comprises silicon oxide (SiO₂) and has a thickness in a range of from 1 nm to 50 nm.

10. The method of claim 1, further comprising trimming the plurality of nanosheets before forming the cladding material to reduce a thickness of the plurality of nanosheets from an initial thickness in a range of from 6 nm to 8 nm to a reduced thickness in a range of from 2 nm to 3 nm.

11. The method of claim 1, further comprising forming a high-K metal gate after removing the oxide film from the cladding material.

12. The method of claim 1, wherein the method is performed in situ in an integrated processing tool.

13. The method of claim 1, wherein the semiconductor device comprises a gate-all-around (GAA) transistor.

14. The method of claim 1, comprising repeating oxidizing, annealing the plurality of nanosheets, and removing the oxide film for a predetermined number of cycles.

15. A method of manufacturing a semiconductor device, the method comprising:
selectively etching a superlattice structure on a substrate, the superlattice structure comprising a plurality of first layers of silicon (Si) and a plurality of second layers of silicon germanium (SiGe) alternatingly arranged in a plurality of stacked pairs extending between a source region and a drain region, the source region formed adjacent a first end of the superlattice structure and the drain region formed adjacent a second opposing end of the superlattice structure, wherein selectively etching the superlattice structure removes each of the plurality of second layers to form a plurality of voids in the superlattice structure and a first plurality of nanosheets comprising the plurality of first layers;
forming a cladding material around each of the first plurality of nanosheets;
oxidizing a portion of the cladding material to form an oxide film around the cladding material and form a second plurality of nanosheets;
annealing the second plurality of nanosheets at a temperature of less than or equal to 850° C.; and
removing the oxide film from the cladding material.

16. The method of claim 15, wherein the cladding material comprises silicon germanium (SiGe).

17. The method of claim 16, wherein the cladding material comprises an initial concentration in a range of from 15% to 50% germanium (Ge) and oxidizing increases the initial concentration of the cladding material to an increased concentration in a range of from greater than 50% to 65% germanium (Ge).

18. The method of claim 15, further comprising forming a high-K metal gate in contact with the second plurality of nanosheets.

19. The method of claim 15, wherein the method is performed in situ in an integrated processing tool.

20. The method of claim 15, comprising repeating oxidizing, annealing the second plurality of nanosheets, and removing the oxide film for a predetermined number of cycles.
